(19) United States
(12) Patent Application Publication
(10) Pub. No.: US 2002/0180345 A1
(43) Pub. Date: Dec. 5, 2002

(54) Package structure containing two LEDs

(76) Inventor: Chang Hsiu Hen, Hsin-Chu (TW)

Correspondence Address: Brian R. Coleman, 1400 Page Mill Road, Palo Alto, CA, 94306, US

(21) Appl. No.: 09/909,752

(22) Filed: Jul. 20, 2001

(30) Foreign Application Priority Data
May 29, 2001 (TW) 090113110

(51) Int. Cl. H01L 33/00

(52) U.S. Cl. 313/499

(57) ABSTRACT

The present invention discloses a package structure containing two LEDs (light emitting diodes), which are packaged in cascade and capable of emitting lights with different wavelengths. For example, by packaging a yellow LED die above a blue LED die or packaging a blue LED die above a yellow LED die, a desaturated blue, desaturated yellow or white light can be obtained when a blue light is emitted through a yellow light or a yellow light is emitted through a blue light. The present invention can be a single-anode-single-cathode or a double-anode-single-cathode package structure, wherein the latter structure can continually change the emitted light in a certain range by adjusting input voltages of the anodes.

### BACKGROUND OF THE INVENTION

1. Field of the Invention

The present invention is related to a package structure and more particularly, to a package structure which is formed by two LEDs (Light Emitting Diodes) packaged in cascade and capable of generating a different light by mixing lights emitted from the package LEDs.

2. Description of Relative Prior Art

As a good light source and device made by semiconductor material, LEDs possesses advantages of small size, long life-time, low driving voltage, rapid response, good oscillation-proof, etc.

By changing the semiconductor materials and device structures, LEDs with different visible and invisible colors can be designed, wherein AlGaAs, InGaAlP and InGaN are suitable for producing LEDs with high luminance over 1000 mcd.

When producing red or infrared LEDs with high luminance by AlGaAs, an LPE process and DE structure devices are used for industrial mass production.

InGaAlP can be used to produce red, orange, yellow and yellow-green LEDs, and an MOVPE (Metal Organic Vapor Physical Epitaxy) process, double hetero (DH) junction structures, and quantum well (QW) structures are provided in efficient mass production. FIG. 1A shows the cross section of the traditional InGaAlP/GaAs or InGaAlP/GaP yellow semiconductor LEDs 10, wherein an InGaAlP epitaxial layer 14 is formed on an n-type on an n-type GaAs substrate 13. A positive bond pad 11 is formed by gold (Au) for being connected to an anode package leg, and a negative bond pad 12 is formed by Al or Au for being connected to a cathode package leg.

InGaN is suitable for producing green, blue and ultra-violet LEDs with high luminance by high temperature MOVPE processes, wherein DH structures and QW structures are used, too. FIG. 1B shows the cross section of the traditional blue LED die 20, wherein a substrate 23 is formed by transparent sapphire. An upper p-type InGaN epitaxial layer 25 and a lower n-type InGaN epitaxial layer 24 are deposited on the substrate 23. A positive bond pad 21 is formed on the p-type InGaN for being connected to an anode package leg, and a negative bond pad 22 is formed on the n-type InGaN for being connected to a cathode package leg. Alternatively, the n-type InGaN epitaxial layer 25 can be epytaxied on the p-type InGaN epitaxial layer 24. As shown in FIG. 1B, the sapphire substrate 23 as a support base results in a different connecting type for the negative bond pad 22 from FIG. 1A.

Compared with general lamps, white LEDs have advantages of no heat generated and more environmental familiar than fluorescent or mercury lamps. Therefore, there are many countries begin to develop this technology when concerning about the energy crisis, although the white LEDs are even much more expensive than other lamps nowadays.

In general, white light is obtained by mixing lights of two compensatory wavelengths, for example, blue and yellow, or three wave lengths, for example, red, green and blue (R.G.B). Currently, in order to obtain white LEDs with high luminance, the following methods are usually used.

The first method is to package the red, green and blue LED dice in the same package body at the same plane and mix the R.G.B. lights to obtain white light. However, such method creates more than four package legs and a larger volume, which is not expected by users. Moreover, three colors can be still observed at near field, and the white light is obtained only at far field.

Another method is to apply fluorescent material with the blue LEDs, wherein Japanese Nichia Co. has disclosed a white LED in U.S. Pat. No. 5,998,925. In this disclosure, a fluorescent material yttrium-aluminum-garnet fluorescent material (YAG phosphor) activated with cerium is coated on InGaN blue LED dice. When the blue light emitted from the blue LED dice lights on the fluorescent material, a yellow light compensatory for the blue light with respect to the white light is generated. According to the lens principle, a white light can be then obtained by mixing the blue light and the compensatory yellow light. However, the fluorescent material is consumed quickly. According to a test, the luminance of this white LED decays about 20 percent after 1,000 hours, so that this product is limited to be applied only in small-sized lighting.

### SUMMARY OF THE INVENTION

The object of the present invention is to provide a package structure containing two LEDs, which can generate a different color light.

Another object of the present invention is to provide a package structure containing two LEDs, which can be produced easily and has less package legs and smaller volume.

The other object of the present invention is to provide a package structure containing two LEDs, which will not result in luminance decay, and the generated light can be observed at both near and far fields.

In order to achieve the above objects, the package structure containing two LEDs of the present invention primarily includes: (a) a package set having at least an anode package leg and a cathode package leg, wherein the cathode package leg has a recess; (b) a first LED die having a positive bond pad and a negative bond pad, and being packaged in the recess of the package set; (c) a second LED die having a positive bond pad and a negative bond pad, and being packaged upon the recess; and (d) a plurality of bonding wires for electrically connecting the positive bond pads of the first LED die and the second LED die to the anode package leg of the package set; wherein the first and second LED dice abovementioned can emit lights with different wavelengths respectively.

The negative bond pad of the first LED die can be attached on the recess, and the negative bond pad of the second LED die can be connected to the cathode package leg of the package set by a bonding wire. Additionally, a transparent support can be optionally disposed on the recess to support the second LED die.

The package set aforementioned can have one or two anode package legs, so that the positive bond pads of the first LED die and the second LED die can be connected to the same or the respective anode package leg to form a single-anode-single-cathode or double-anode-single-cathode package structure.

In general, the area of the second LED die is larger than that of the first LED die. For example, the first LED die has an area about 36 to 400 mil², and the second LED die has an area about 400 to 900 mil².

The recess of the present invention can be optionally disposed in the cathode package leg or the anode package leg, and the connecting manners between the above elements are similar.

The LED dice used in the present invention are not restricted, but any two LED dice capable of emitting lights with different wavelengths are suitable. For example, a yellow LED die and a blue LED die can be packaged in cascade according the present invention, and then a desaturated blue, desaturated yellow or white light will be obtained.

### BRIEF DESCRIPTION OF THE DRAWINGS

FIGS. 1A and 1B show the cross sections of the traditional yellow and blue LEDs.

FIGS. 2A and 2B show the cross sections of two package structures in accordance with the present invention.

FIG. 3 shows the equivalent circuit of the structures in FIGS. 2A and 2B.

FIGS. 4A and 4B show the cross sections of another two package structures in accordance with the present invention.

FIG. 5 shows the equivalent circuit of the structures in FIGS. 4A and 4B.

FIG. 6 shows the chromaticity diagram.

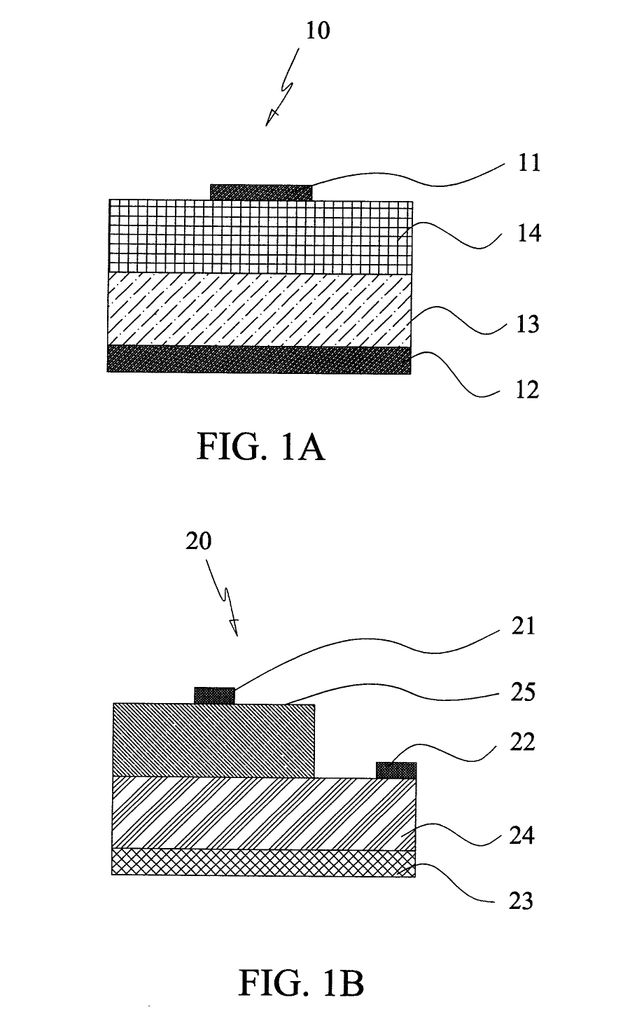

### DETAILED DESCRIPTION OF THE PREFERRED EMBODIMENTS

The present invention provides a package structure containing two LED dice capable of emitting lights with different wavelengths. In the following embodiments, a yellow LED die 10 and a blue LED die 20 are used to mix a yellow light and a blue light by being packaged in cascade, and then a different light can be obtained.

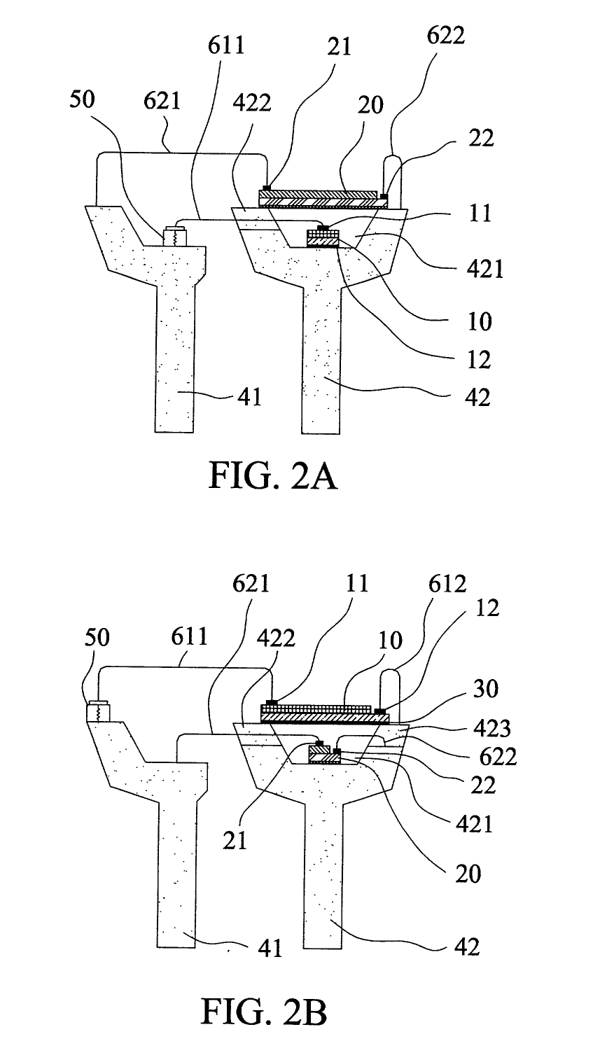

FIG. 2A shows the cross section of the first embodiment of the package structure containing two LEDs in accordance with the present invention. In this embodiment, a package set contains an anode package leg 41 and a cathode package leg 42, wherein the cathode package leg 42 has a recess 421 therein.

The yellow LED die 10 includes a GaAs or GaP substrate 13 and an InGaAlP epitaxial layer 14 formed on the substrate 13. The yellow LED die 10 has a positive bond pad 11 and a negative bond pad 12. The positive bond pad 11 is connected to a resistor 50 by a bonding wire 611 through a wire channel 422 which is then sealed with nontransparent material. The resistor 50 is then connected to the anode package leg 41. The negative bond pad 12 is die bonded on the recess 421 of the cathode package leg 42.

The blue LED die 20 includes a sapphire substrate 23 and an pn junction layer formed on a sapphire substrate 23. The pn junction includes an n-type InGaN epitaxial layer 24 and a p-type InGaN epitaxial layer 25. The blue LED die 20 has a positive bond pad 21 and a negative bond pad 22. The positive bond pad 21 is connected to the anode package leg 41 of the package set by a bonding wire 621, and the negative bond pad 22 is connected to the cathode package leg 42 by a bonding wire 622.

In this embodiment, the yellow LED die 10 has a smaller area about 36 to 400 mil², and preferably 100 mil², and a thickness about 6 to 8 mil. The blue LED die 10 has a larger area about 400 to 900 mil², and a thickness about 2 to 3 mil.

FIG. 2B shows the cross sections of the second embodiment of the package structure containing two LEDs in accordance with the present invention. In this embodiment, the yellow LED die 10 is packaged upon the blue LED die 20. Compared with the first embodiment, this embodiment has several differences listed as follows: (a) the resistor 50 is moved to an upper position of the anode package leg 41 for being easily connected to the positive bond pad 11 of the yellow LED die 10; (b) the yellow LED die 10 is die bonded or epitaxied on a transparent sapphire support 30, so that the negative bond pad 12 of the yellow LED die 10 is connected to the cathode package leg 42 by a bonding wire 612; (c) the negative bond pad 22 of the blue LED die 20 is connected to the recess 421 of the cathode package leg 42 by the bonding wire 622 through another wire channel 423; and (d) the yellow LED die 10 has a larger area about 400 to 900 mil² and a thickness about 4 to 13 mil; and the blue LED die 20 has a smaller area about 36 to 400 mil² and a thickness about 2 to 7 mil.

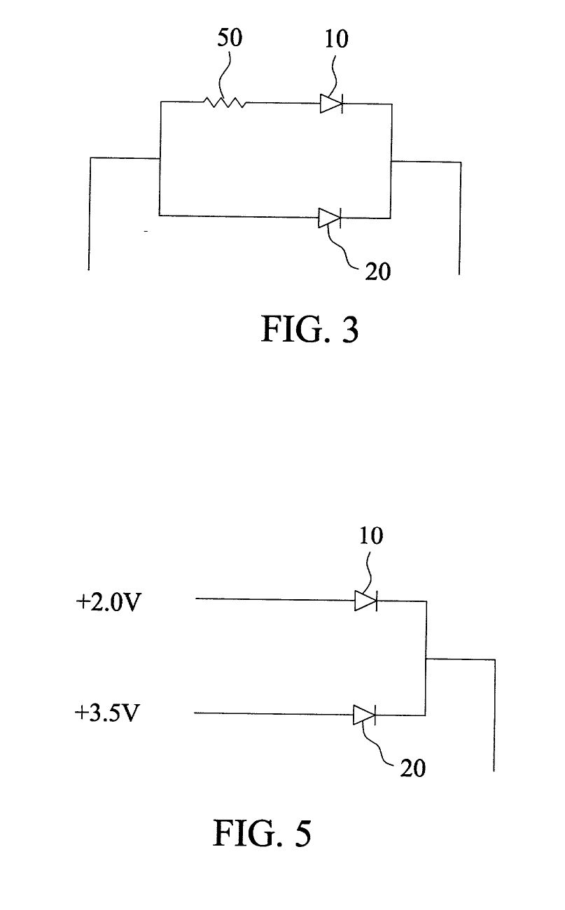

FIG. 3 shows the equivalent circuit of the structures in FIGS. 2A and 2B. Since the yellow LED die 10 with a driving voltage 2 V and the blue LED die 20 with a driving voltage 3.5 V are driven by the same electric source in the first and second embodiments, i.e. a single-anode-single-cathode structure is formed, the resistor 50 is applied to reduce the voltage of the yellow LED die 10. Additionally, by adjusting resistances of the resistor 50, luminance of the yellow LED die can be changed.

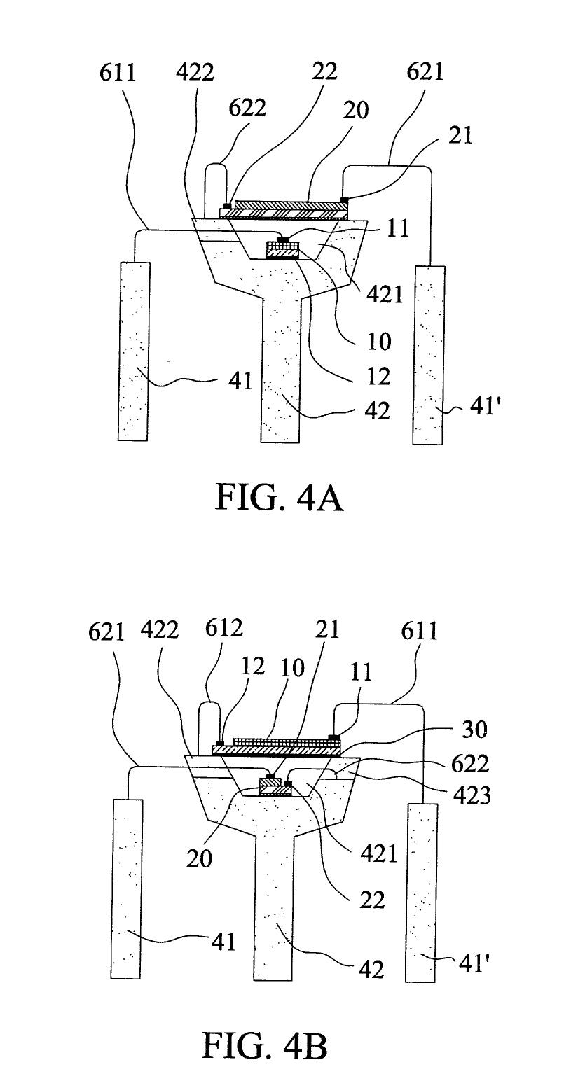

FIG. 4A shows the cross section of the third embodiment of the package structure containing two LEDs in accordance with the present invention. This embodiment is similar to the first one. However, in this embodiment, two anode package legs 41, 41′ are provided for being respectively connected to the positive bond pad 11 of the yellow LED die 10 and the positive bond pad 21 of the blue LED die 20. Therefore, no resistor is necessary here.

FIG. 4B shows the cross section of the fourth embodiment of the package structure containing two LEDs in accordance with the present invention. This embodiment is similar to the second one. However, as the third embodiment, two anode package legs 41, 41′ are provided for being respectively connected to the positive bond pad 11 of the yellow LED die 10 and the positive bond pad 21 of the blue LED die 20. Therefore, no resistor is necessary here, either.

FIG. 5 shows the equivalent circuit of the structures in FIGS. 4A and 4B, in which the yellow LED die 10 and the blue LED die 20 are simply electrically connected in parallel. Since the yellow LED die 10 and the blue LED die 20 are driven by different electric source in the third and fourth embodiments, i.e. a double-anode-single-cathode structure is formed, a 2.0 V voltage source and a 3.5 V voltage source are supplied respectively. Such arrangement has an advantage of saving electric energy.

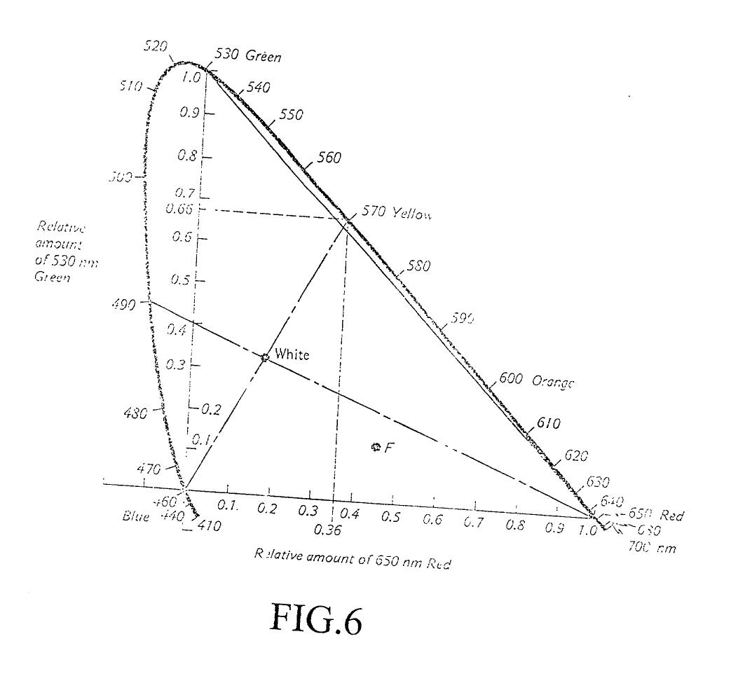

FIG. 6 shows the chromaticity diagram, wherein points A and B are yellow with wavelength 570 nm and blue with wavelength 460 nm. Accordingly, by adjusting the input voltage of the anode package legs 41, 41′, the mixed light can be changed along with a line A-B, i.e. blue-desaturated blue-white-desaturated yellow-almost saturated yellow can be obtained continually. Similarly, if a 650-nm red light emitted from a red LED die and a 530-nm green light emitted from a green LED die are mixed in accordance with the package structure of the present invention, lights of different colors can be obtained along with a line C-D by adjusting the voltages of two anode package legs.

In the present invention, the packaged LEDs are not restricted, which can be different colors and made by different materials. The abovementioned embodiments are only examples for explaining the present invention. Any similar product modified according to this disclosure should be regarded within the scope of the present invention.

What is claimed is:

1. A package structure containing two LEDs, comprising:
(a) a package set having at least an anode package leg and a cathode package leg, wherein the cathode package leg has a recess;
(b) a first LED die having a positive bond pad and a negative bond pad, and being packaged in the recess of the package set;
(c) a second LED die having a positive bond pad and a negative bond pad, and being packaged upon the recess; and
(d) a plurality of bonding wires for electrically connecting the positive bond pads of the yellow LED die and the blue LED die to the anode package leg of the package set;
wherein the first and second LED dice can respectively emit lights with different wavelengths.

2. The package structure of claim 1, wherein the negative bond pad of the first LED die is attached on the recess.

3. The package structure of claim 1, wherein the negative bond pad of the second LED die is connected to the cathode package leg of the package set by a bonding wire.

4. The package structure of claim 1, wherein the second LED die is supported by a transparent support.

5. The package structure of claim 1, wherein the package set has only one anode package leg connected to the positive bond pads of the first LED die and the second LED die, whereby a single-anode-single-cathode package structure is formed.

6. The package structure of claim 1, wherein the package set has two anode package legs respectively connected to the positive bond pads of the first LED die and the second LED die, whereby a double-anode-single-cathode package structure is formed.

7. The package structure of claim 1, wherein the two anode package legs are supplied with adjustable voltages.

8. The package structure of claim 1, wherein the area of the second LED die is larger than that of the first LED die.

9. The package structure of claim 1, wherein the first LED die has an area about 36 to 400 mil².

10. The package structure of claim 1, wherein the second LED die has an area about 400 to 900 mil².

11. The package structure of claim 1, wherein the lights emitted from the first LED die and the second LED die are compensatory.

12. The package structure of claim 1, wherein the first LED die is a yellow LED die.

13. The package structure of claim 12, wherein the yellow LED die comprises a GaAs or GaP substrate and an InGaAlP layer epitaxied on the substrate.

14. The package structure of claim 1, wherein the second LED die is a blue LED die.

15. The package structure of claim 14, wherein the blue LED die comprises a sapphire substrate and an InGaN pn junction layer attached or deposited on the sapphire substrate.

16. The package structure of claim 1, wherein the first LED die is a blue LED die.

17. The package structure of claim 16, wherein the blue LED die comprises a sapphire substrate and an InGaN pn junction layer attached or deposited on the sapphire substrate.

18. The package structure of claim 1, wherein the second LED die is a yellow LED die.

19. The package structure of claim 18, wherein the yellow LED die comprises a GaAs or GaP substrate and an InGaAlP layer epitaxied on the substrate.
